(19) United States
(12) Patent Application Publication
(10) Pub. No.: US 2024/0260313 A1
(43) Pub. Date: Aug. 1, 2024

(54) LIGHT EMITTING DISPLAY DEVICE

(71) Applicant: LG Display Co., Ltd., Seoul (KR)

(72) Inventors: Euijun KIM, Paju-si (KR); Youngho KIM, Paju-si (KR)

(73) Assignee: LG Display Co., Ltd., Seoul (KR)

(21) Appl. No.: 18/521,893

(22) Filed: Nov. 28, 2023

(30) Foreign Application Priority Data
Jan. 30, 2023 (KR) 10-2023-0012123

(51) Int. Cl. H10K 59/121; H10K 59/122; H10K 59/126; H10K 59/80

(52) U.S. Cl. CPC H10K 59/121; H10K 59/122; H10K 59/126; H10K 59/879

(57) ABSTRACT

An ultra-high resolution light emitting display which prevents light leakage and lateral leakage current is discussed. The light emitting display includes a plurality of pixels disposed on a substrate, and a first area and a second area both disposed in each of the pixels. The pixels include a first pixel and a second pixel, and the first area of the first pixel is disposed adjacent to the second area of the second pixel.

### CROSS-REFERENCE TO RELATED APPLICATIONS

This application claims priority to Korean Patent Application No. 10-2023-0012123 filed in the Republic of Korea on Jan. 30, 2023, the entire contents of which are hereby expressly incorporated by reference into the present application.

### BACKGROUND

### Field

The present disclosure relates to an ultra-high resolution light emitting display which prevents light leakage and lateral leakage current.

### Discussion of the Related Art

Among display device, light emitting display devices have a high aperture ratio and can provide excellent display quality with high luminance using low power consumption. As the resolution of the display device increases beyond 4K ppi (pixel per inch), the number of pixels increases, and accordingly, the size of one pixel can inevitably decrease.

Additionally, as the number of pixels increases, a gap between the emission areas of neighboring pixels can be narrowed. Accordingly, light leakage can occur between the neighboring emission areas, or lateral leakage current can occur. In this case, the image quality can be distorted, and the reliability of the display device can decrease. Therefore, in realizing ultra-high resolution, it is desirable to develop a light emitting display device with a new structure that improves image quality by preventing the light leakage or the lateral leakage current.

### SUMMARY OF THE DISCLOSURE

The present disclosure addresses the problems and limitations associated with the related art including the limitation described above.

An aspect of the present disclosure is to provide a light emitting display having a structure with ultra-high-density resolution that prevents light leakage and lateral leakage current between neighboring pixels.

Another aspect of some embodiments of this present disclosure is to provide a light emitting display device with high luminance (or brightness) relative to the power consumption by ensuring the maximum emission area in the light emitting display device implementing ultra-high resolution.

In order to accomplish the above-mentioned features, a light emitting display according to the present disclosure can include a plurality of pixels disposed on a substrate, and a first area and a second area disposed in each of pixels. The plurality of pixels include a first pixel and a second pixel, and the first area of the first pixel is adjacent to the second area of the second pixel.

In one embodiment, the first area includes an emission area. The second area includes a non-emission area.

In one embodiment, the light emitting display device further includes a light shielding layer disposed in the non-emission area.

In one embodiment, the emission areas are arrayed in a zig-zag shape along a horizontal direction and a vertical direction.

In one embodiment, the emission areas are disposed in a diagonal direction.

In one embodiment, the emission area includes a pixel electrode; an emission layer on the pixel electrode; and a common electrode on the emission layer.

In one embodiment, the light emitting display device further includes a micro-lens under the pixel electrode.

In one embodiment, the light emitting display device further includes a bank covering circumferential area of the pixel electrode, and exposing middle portions of the pixel electrode.

The micro-lens overlaps a portion of the pixel electrode and a portion of bank outside the emission area.

In one embodiment, the bank includes a black material.

In one embodiment, the first area of the first pixel and the second area of the second pixel are adjacent in a horizontal direction on a surface of the substrate.

In one embodiment, the first area of the first pixel and the second area of the second pixel are adjacent in a vertical direction on a surface of the substrate.

The light emitting display according to one or more aspects of the present disclosure can ensure a maximum aperture ratio, which is the ratio of the emission area in one pixel. In addition, the light emitting display device according to an aspect of the present disclosure has an increased resolution, so that the light leakage or the lateral leakage current may not occur between neighboring emission areas even though the gap between neighboring pixels is narrowed. Further, the light emitting display device according to an aspect of the present disclosure provides a high aperture ratio and ultra-high density pixel resolution without leakage current, and thus a low power display device that provides brighter luminance with the same power consumption can be implemented.

The light emitting display device according to an aspect of the present disclosure can improve light extraction efficiency by providing a micro lens. In particular, by disposing a light shielding layer and a driving element between two neighboring emission areas, color deviation (or distortion) due to reflection of external light does not occur in the lateral (or horizontal) viewing angle direction. By providing a micro lens, the light extraction rate is increased to provide a high luminance image while providing high quality image information with reduced image distortion due to color deviation in the lateral viewing angle direction.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view illustrating an overall structure of a light emitting display according to an embodiment of the present disclosure.

FIG. 2 is an enlarged plan view illustrating a structure of two neighboring pixels included in the light emitting display according to an embodiment of the present disclosure.

FIG. 3 is an enlarged cross-sectional view, along the cutting line I-I′ in FIG. 2, illustrating a structure of one pixel in a light emitting display device according to an embodiment of the present disclosure.

FIG. 4 is an enlarged plan view illustrating an arrangement structure of pixels disposed in a light emitting display device according to a first embodiment of the present disclosure.

FIG. 5 is an enlarged cross-sectional view, along the cutting line II-II′ in FIG. 4, illustrating a structure of a light emitting display device according to the first embodiment of the present disclosure.

FIG. 6 is a cross-sectional view illustrating a structure for ensuring a maximum aperture ratio in the light emitting display device according to the first embodiment of the present disclosure.

FIG. 7 is an enlarged plan view illustrating a structure of a light emitting display according to a second embodiment of the present disclosure.

FIG. 8 is an enlarged plan view illustrating a structure of 4-pixel array in a light emitting display device according to a third embodiment of the present disclosure.

FIG. 9 is an equivalent circuit diagram for one pixel in the light emitting display device according to the third embodiment of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration can unnecessarily obscure an important point of the present disclosure, a detailed description of such known function of configuration can be omitted.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements can be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third layer or element can be interposed there-between. Further, if a first element is described as positioned “on” a second element, it does not necessarily mean that the first element is positioned above the second element in the figure. The upper part and the lower part of an object concerned can be changed depending on the orientation of the object. Consequently, where a first element is described as positioned “on” a second element, the first element can be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous can be included unless a more limiting term, such as “just,” “immediate(ly),” or “direct(ly),” is used.

It will be understood that, although the terms “first,” “second,” and the like can be used herein to describe various elements, these elements should not be limited by these terms as they are not used to define a particular order or sequence. These terms are used only to distinguish one element from another. For example, a first element could be termed a second element, and, similarly, a second element could be termed a first element, without departing from the scope of the present disclosure.

In describing the components of the present disclosure, terms such as ‘first’, ‘second’, ‘A’, ‘B’, ‘(a)’ and ‘(b)’ can be used. These terms are only used to distinguish the components from other components, and the nature, sequence, order or number of the corresponding component is not limited by the term. Where an element is described as being “linked”, “coupled,” or “connected” to another element, that element can be directly or indirectly connected to that other element unless otherwise specified. It is to be understood that additional element or elements can be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Hereinafter, various examples of a display apparatus according to the present disclosure will be described in detail with reference to the attached drawings. All the components of each display apparatus according to all embodiments of the present disclosure are operatively coupled and configured. In the present application, a display device or a display apparatus can be referred to as a display. Since a scale of each of elements shown in the accompanying drawings can be different from an actual scale for convenience of description, the present disclosure is not limited to the scale shown in the drawings.

The scales of the elements shown in the drawings have different scales from actual ones for convenience of explanation, so they are not limited to the scales shown in the drawings.

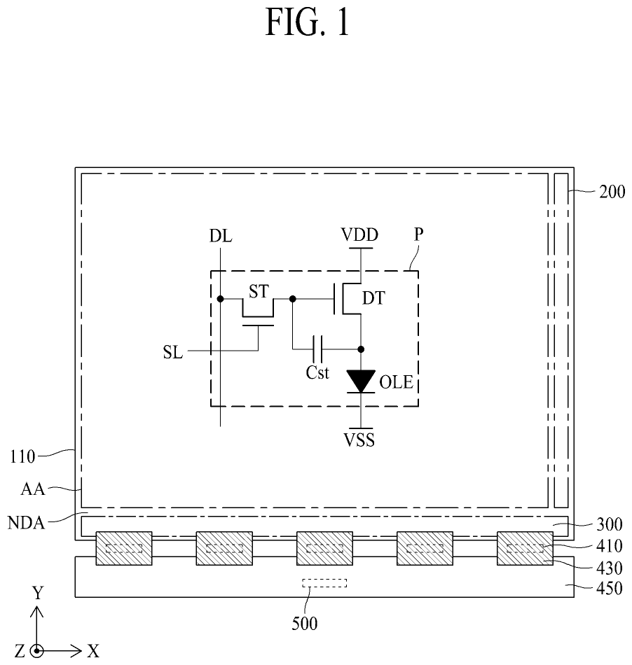

FIG. 1 is a schematic plan view illustrating an overall structure of a light emitting display (light emitting display device) according to an embodiment of the present disclosure. In FIG. 1, an X-axis refers to the direction parallel to a scan line, a Y-axis refers to the direction of a data line, and a Z-axis refers to a height direction of the display device. The circuit diagram shown in FIG. 1 is an equivalent circuit diagram illustrating the structure of one pixel disposed in the light emitting display device according to an embodiment of the present disclosure.

Referring to FIG. 1, the light emitting display comprises a substrate 110, a gate (or scan) driver 200, a pad portion 300, a source driving IC (Integrated Circuit) 410, a flexible circuit film 430, a circuit board 450, and a timing controller 500.

The substrate 110 can include an electrical insulating material or a flexible material. The substrate 110 can be made of a glass, a metal or a plastic, but it is not limited thereto. When the electroluminescence display is a flexible display, the substrate 110 can be made of the flexible material such as plastic. For example, the substrate 110 can include a transparent polyimide material.

The substrate 110 can include a display area (active area) AA and a non-display area (non-active area) NDA. The display area AA, which is an area for representing (or, displaying) video images, can be defined as the majority middle area of the substrate 110, but it is not limited thereto. In the display area AA, a plurality of scan lines SL (or gate lines), a plurality of data lines DL and a plurality of pixels P can be formed or disposed. Each of pixels P can include a plurality of sub pixels. Each of sub pixels includes the scan line SL and the data line DL, respectively.

The non-display area NDA, which is an area not representing video images, can be defined at the circumference areas of the substrate 110 surrounding all or some of the display area DA. In the non-display area NDA, the gate driver 200 and the pad portion 300 can be formed or disposed.

The gate driver 200 can supply the scan (or gate) signals to the scan lines according to the gate control signal received from the timing controller 500 through the pad portion 300. The gate driver 200 can be formed at the non-display area NDA disposed at a circumferential area of the display area AA on the substrate 110, as a GIP (Gate driver In Panel) type. Here, GIP type preferably means that the gate driver 200 is directly formed on the substrate 110. For example, the gate driver 200 can include a shift register. The GIP type refers to a structure in which transistors included in the shift register of the gate driver 200 are formed directly on the substrate 100.

The data pad portion 300 can be disposed in the non-display area NDA disposed at one edge of the display area AA of the substrate 100. The pad portion 300 includes data pads connected to each of the data lines DL, driving current pads connected to the driving current line, a high-potential pad receiving a high-level voltage, and a low-potential pad receiving a low-level voltage.

The source driving IC 410 can receive the digital video data and the source control signal from the timing controller 500. The source driving IC 410 can convert the digital video data into the analog data voltages according to the source control signal and then supply that to the data lines. When the source driving IC 410 is made as a chip type, it can be installed on the flexible circuit film 430 as a COF (Chip On Film) or COP (Chip On Plastic) type.

The flexible circuit film 430 can include a plurality of first link lines connecting the pad portion 300 to the source driving IC 410, and a plurality of second link lines connecting the pad portion 300 to the circuit board 450. The flexible circuit film 430 can be attached on the pad portion 300 using an anisotropic conducting film, so that the pad portion 300 can be connected to the first link lines of the flexible circuit film 430.

The circuit board 450 can be attached to the flexible circuit film 430. The circuit board 450 can include a plurality of circuits implemented as the driving chips. For example, the circuit board 450 can be a printed circuit board or a flexible printed circuit board.

The timing controller 500 can receive the digital video data and the timing signal from an external system board through the line cables of the circuit board 450. The timing controller 500 can generate a gate control signal for controlling the operation timing of the gate driver 200 and a source control signal for controlling the source driving IC 410, based on the timing signal. The timing controller 500 can supply the gate control signal to the gate driver 200 and supply the source control signal to the source driving IC 410. Depending on the product types, the timing controller 500 can be formed as one chip with the source driving IC 410 and mounted on the substrate 110.

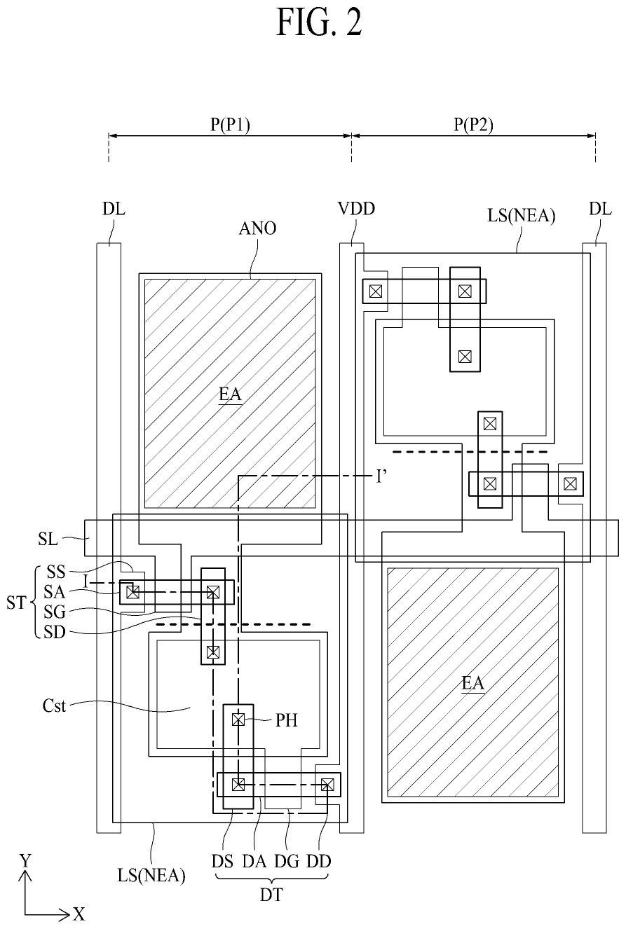

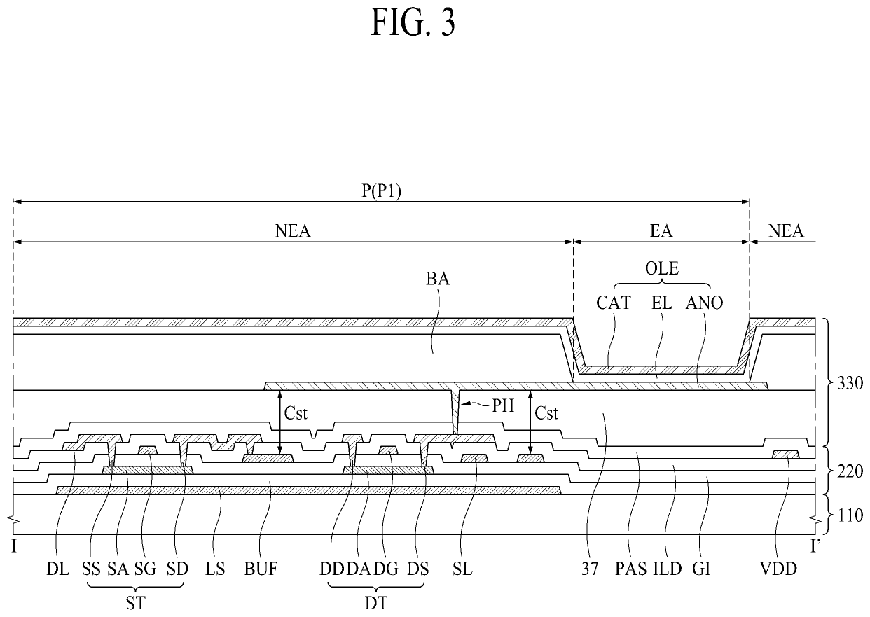

Hereinafter further referring to the FIGS. 2 and 3, a pixel structure of alight emitting display device according to an embodiment of the present disclosure will be described. Particularly, FIG. 2 is an enlarged plan view illustrating a structure of two neighboring pixels included in the light emitting display according to an embodiment of the present disclosure. FIG. 3 is an enlarged cross-sectional view, along the cutting line I-I′ in FIG. 2, illustrating a structure of one pixel in a light emitting display device according to an embodiment of the present disclosure.

A light emitting display device according to the present disclosure includes a plurality of pixels P arrayed in a matrix manner (or, form). Each pixel P of the light emitting display can be defined by a scan line SL, a data line DL and a driving current line VDD. One pixel P of the light emitting display can include a switching thin film transistor ST, a driving thin film transistor DT, a light emitting diode OLE and a storage capacitor Cst. The driving current line VDD can be supplied with a high-level voltage for driving the light emitting diode OLE.

A switching thin film transistor ST and a driving thin film transistor DT can be formed on a substrate SUB. For example, the switching thin film transistor ST can be disposed at the portion where the scan line SL and the data line DL is crossing. The switching thin film transistor ST can include a gate electrode SG, a semiconductor layer SA, a source electrode SS and a drain electrode SD. The gate electrode SG of the switching thin film transistor ST can be connected to the scan line SL or branched from the scan line SL. The semiconductor layer SA can be disposed as crossing the gate electrode SG. The overlapped portions of the semiconductor layer SA with the gate electrode SG can be defined as the channel area. The source electrode SS can be connected to or branched from the data line DL and the drain electrode SD can be connected to the driving thin film transistor DT. One side of the semiconductor layer SA is connected to the source electrode SS, and the other side of the semiconductor layer SA is connected to the drain electrode SD. By supplying the data signal to the driving thin film transistor DT, the switching thin film transistor ST can play a role of selecting a pixel which would be driven.

The driving thin film transistor DT can play a role of driving the light diode OLE of the selected pixel by the switching thin film transistor ST. The driving thin film transistor DT can include a gate electrode DG, a semiconductor layer DA, a source electrode DS and a drain electrode DD. The gate electrode DG of the driving thin film transistor DT can be connected to the drain electrode SD of the switching thin film transistor ST. For example, the gate electrode DG of the driving thin film transistor DT can be connected to or extended from the drain electrode SD of the switching thin film transistor ST. In the driving thin film transistor DT, the drain electrode DD id connected to or branched from the driving current line VDD, and the source electrode DS is connected to a pixel electrode ANO of the light emitting diode (or light emitting element) OLE. The semiconductor layer DA can be disposed as crossing the gate electrode DG. The overlapped area of the semiconductor layer DA with the gate electrode DG can be defined as a channel area. The source electrode DS is connected to one side of the semiconductor layer DA, and the drain electrode DD is connected to the other side of the semiconductor layer DA. A storage capacitor Cst can be disposed between the gate electrode DG of the driving thin film transistor DT and the anode electrode ANO of the light emitting diode OLE.

The light emitting diode OLE can include a pixel electrode ANO, (or anode electrode) an emission layer EL and a common electrode CAT (or cathode electrode). The pixel electrode ANO is disposed within the pixel P. The emission layer EL and the common electrode CAT are sequentially stacked on the pixel electrode ANO. The portion of the pixel electrode ANO that contact the emission layer EL and generates light can be defined as an emission area EA. At the pixel P, the portion which does not emit light can be defined as a non-emission area NEA.

The light emitting diode OLE can display an image by emitting light according to a current controlled by the driving thin film transistor DT. The driving thin film transistor DT is disposed between the driving current line VDD and the light emitting diode OLE. The driving thin film transistor DT controls the amount of the electric currents flowing from the driving current line VDD to the light emitting diode OLE according to the voltage difference between the gate electrode DG and the source electrode DS. The pixel electrode ANO of the light emitting diode OLE is connected to the source electrode DS of the driving thin film transistor DT, and the common electrode CAT is connected to the low-power line VSS to which a low-level voltage is suppled. Accordingly, the light emitting diode OLE is driving by the current flowing from the driving current line VDD to the low-power line VSS in accordance with the operation of the driving thin film transistor DT.

FIG. 2 shows two pixels P neighboring each other along the X-axis. For example, a first pixel P1 can be disposed at a left side, and a second pixel P2 can be disposed at a right side. Particularly, FIG. 2 shows a bottom emission type light emitting display device. Each of the first pixel P1 and the second pixel P2 has a rectangular shape with a short side along the X-axis and a long side along the Y-axis.

In the first pixel P1, an emission area EA is disposed at an upper side along the Y-axis, and a non-emission area NEA is disposed at a lower side along the Y-axis. The non-emission area NEA includes driving elements. A light shielding layer LS can be formed as covering entire area of the non-emission area NEA. The second pixel P2 has a vertically inverted structure compared to the first pixel P1. In detail, the second pixel P2 has an emission area EA disposed at the lower side along the Y-axis, and a non-emission area NEA, including the driving elements, is disposed at the upper side along the Y-axis. The light shielding layer LS can be formed as covering entire of the non-emission area NEA.

In each of the first pixel P1 and the second pixel P2 shown in FIG. 2, the drain electrode SD of the switching thin film transistor ST is connected to the gate electrode DG of the driving thin film transistor DT. The gate electrode DG of the driving thin film transistor DT has widened area at the connection portion with the drain electrode SD of the switching thin film transistor ST. This widened area of the gate electrode DG of the driving thin film transistor DT can be used one electrode of the storage capacitor Cst. The source electrode DS of the driving thin film transistor DT is connected to the pixel electrode ANO via a pixel contact hole PH.

In FIG. 2, the dotted line refers to a cutting line for performing a repair process in which the connection between the pixel electrode ANO and the thin film transistors ST and DR is disconnected when a defect occurs in the thin film transistors ST and DT connected to the pixel electrode ANO. The cutting line can be arranged to simultaneously cut the parts where the switching thin film transistor ST and the driving thin film transistor DT a connected, and the part where the driving thin film transistor DT is connected to the pixel electrode ANO of the light emitting diode OLE. For example, as shown in FIG. 2, the cutting line can be disposed at the part where the drain electrode SD of the switching thin film transistor ST is connected to the storage electrode Cst which is formed by extending from the gate electrode DG of the driving thin film transistor DT.

Due to the above-mentioned structure, the cutting line for repair can be disposed at one area. Therefore, just with one repairing process, the defected pixel can be darkened. In addition, the two portions for repairing can be integrated into one portion, so the margin area for the arrangement of the cutting line can be minimized. By arranging elements in this way, as the margin area can be minimized, a larger display area can be secured, and/or other elements can be added. For example, a size of the storage capacitor can be enlarged.

Referring to FIG. 3, the cross-sectional structure will be described. On the substrate 110, a light shielding layer LS is formed. It is preferable that the light shielding layer LS is disposed to correspond to the non-emission area NEA. On the light shielding layer LS, a buffer layer BUF is deposited as covering entire surface of the substrate 110.

Within the light shielding layer LS on the buffer layer BUF, semiconductor layers SA and DA are formed. In detail, the semiconductor layer SA of the switching thin film transistor ST and the semiconductor layer DA of the driving thin film transistor DT are formed separately on the same layer. A gate insulating layer GI is deposited over the semiconductor layers SA and DA and the buffer layer BUF.

Gate electrodes SG and DG are formed on the gate insulating layer GI as overlapping with the semiconductor layers SA and DA, respectively. In detail, the gate electrode SG of the switching thin film transistor ST is formed as overlapping with the semiconductor layer SA of the switching thin film transistor ST. Further, the gate electrode DG of the driving thin film transistor DT is formed as overlapping with the semiconductor layer DA of the driving thin film transistor DT.

An intermediate insulating layer ILD is deposited on the gate electrodes SG and DG and the gate insulating layer GI as covering entire surface of the substrate 110. Source electrodes SS and DS and drain electrodes DS and DD are formed on the intermediate insulating layer ILD.

The drain electrode SD of the switching thin film transistor ST is connected to the gate electrode DG of the driving thin film transistor DT. Further, the gate electrode DG of the driving thin film transistor DT can have an expanded portion to overlap with the pixel electrode ANO. The storage capacitor Cst can be formed at this expanded portion of the gate electrode DG overlapped with the pixel electrode ANO.

On the substrate 110 having the thin film transistors ST and DT, a passivation layer PAS can be deposited. The passivation layer PAS preferably is made of an inorganic material such as silicon oxide (SiOx) or silicon nitride (SiNx). This stacked structure can be collectively referred to as the driving element layer 220. A planarization layer PL can be deposited on the passivation layer PAS. The planarization layer PL can be a thin film for flattening or evening the non-uniform surface of the substrate 110 on which the thin film transistors ST and DT are formed. To do so, the planarization layer PL can be made of the organic materials.

A pixel contact hole PH is formed at the planarization layer PL. The pixel contact hole PH is respectively disposed for each pixel P, and exposes a portion of the source electrode DS of the driving thin film transistor DT.

A pixel electrode ANO is formed on the planarization layer PL. The pixel electrode ANO is connected to the source electrode DS of the driving thin film transistor DT via the pixel contact hole PH. For the bottom emission type light emitting display, the pixel electrode ANO can include a transparent conductive material. For example, the pixel electrode ANO can include an oxide conductive material such as indium-zinc-oxide (IZO) or indium-tin-oxide (ITO).

For the top emission type light emitting display, the pixel electrode ANO can include a metal material having excellent light reflectance. For example, the pixel electrode ANO can be made of any one metal material selected from silver (Ag), aluminum (Al), molybdenum (Mo), gold (Au), magnesium (Mg), calcium (Ca) and barium (Ba), or two or an alloy of two or more of them. The present disclosure will be explained with the bottom emission type.

A bank BA is formed on the pixel electrode ANO. The bank BA covers the circumferential areas of the pixel electrode ANO and exposes the middle portions of the pixel electrode ANO to define an emission area EA.

An emission layer EL is deposited on the pixel electrode ANO and the bank BA. The emission layer EL can be formed on the pixel electrode ANO and the bank BA as covering entire display area AA of the substrate 110. For an organic light emitting display device, the emission layer EL can include an organic material. For an inorganic light emitting display device, the emission layer EL can include an inorganic material.

For an example, the emission layer EL can include two or more stacked emission portions for emitting white light. In detail, the emission layer EL can include a first emission layer providing first color light and a second emission layer providing second color light, for emitting the white light by combining the first color light and the second color light.

In another example, the emission layer EL can include at least any one of blue-light emission layer, green-light emission layer and red-light emission layer as corresponding to the color allocated to the pixel. In addition, the light emitting diode OLE can further include at least one functional layer for enhancing the light emitting efficiency and/or the service lifetime of the emission layer EL.

A common electrode CAT can be disposed on the emission layer EL. The common electrode CAT can be stacked on the emission layer EL as being surface contact each other. The common electrode CAT can be formed as one sheet element over entire area of the substrate 110 as being commonly connected whole emission layers EL disposed at all pixels. As the present disclosure is related to the bottom emission type display device, the common electrode CAT can include metal material having excellent light reflection ratio. For example, the common electrode CAT can include at least any one of silver (Ag), aluminum (Al), molybdenum (Mo), gold (Au), magnesium (Mg), calcium (Ca), or barium (Ba).

For the top emission type light emitting display, the common electrode CAT can include a transparent conductive material. For example, the common electrode CAT can include an oxide conductive material such as indium-zinc-oxide (IZO) or indium-tin-oxide (ITO).

A light emitting diode OLE can be formed at the emission area where the pixel electrode ANO, the emission layer EL and the common electrode CAT are sequentially stacked.

An encapsulation layer can be further deposited on the light emitting diode OLE. The encapsulation layer can include a first inorganic encapsulation layer, an organic encapsulation layer and a second inorganic encapsulation layer, sequentially stacked each other.

### First Embodiment

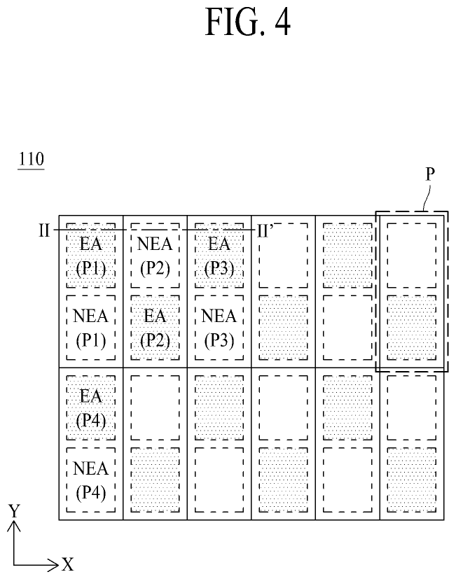

Hereinafter, referring to FIG. 4, an arrangement structure of the pixels in the light emitting display device according to a first embodiment of the present disclosure will be explained. FIG. 4 is an enlarged plan view illustrating an arrangement structure of pixels disposed in a light emitting display device according to the first embodiment of the present disclosure.

The light emitting display according to the first embodiment of the present disclosure includes a plurality of pixels P arrayed in a matrix manner (or, form) on a substrate 110. For example, a first pixel P1, a second pixel P2 and a third pixel P3 can be arranged sequentially along an X-axis. In addition, the first pixel P1 and a fourth pixel P4 is sequentially arranged along a Y-axis.

Each pixel P includes an emission area EA and a non-emission area NEA. For example, the emission area EA is disposed at one side along the Y-axis, and the non-emission area EA is disposed at the other side along the Y-axis. Preferably, between two neighboring pixels P, the emission area EA and the non-emission area NEA are arranged adjacent to each other.

In detail, the arrangement relationship between three pixels P1, P2 and P3 arranged along the Y-axis will be described. The first pixel P1 has an emission area EA at an upper side, and a non-emission area NEA at a lower side. The second pixel P2 has an emission area EA at a lower side, and a non-emission area NEA at an upper side. Further, the third pixel P3, like the first pixel P1, has an emission area EA at an upper side and a non-emission area NEA at a lower side. As a result, along the X-axis, the emission area EA and the non-emission area NEA are alternately arranged.

Next, the arrangement relationship between tow pixels P1 and P4 arranged along the Y-axis will be described. The first pixel P1 includes an emission area EA at an upper side, and a non-emission area NEA at a lower side. The fourth pixel P4 includes a non-emission area NEA at an upper side, and an emission area EA at a lower side. As a result, along the Y-axis, the emission area EA and the non-emission area NEA are alternately arranged.

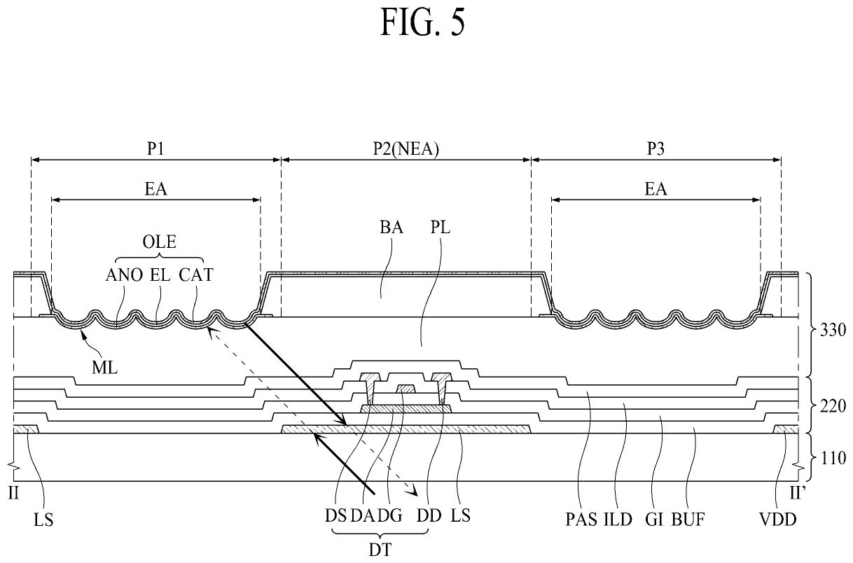

Hereinafter, referring to FIG. 5, a cross-sectional structure of the light emitting display device according to the first embodiment will be explained. FIG. 5 is an enlarged cross-sectional view, along the cutting line II-II′ in FIG. 4, illustrating a structure of a light emitting display device according to the first embodiment of the present disclosure. Specifically, FIG. 5 shows a bottom emission type light emitting display device in which a plurality of micro-lens ML is disposed within the emission area EA.

The first pixel P1, the second pixel P2 and the third pixel P3 are sequentially arrayed along the X-axis. In particular, the emission area EA of the first pixel P1, the non-emission area NEA of the second pixel P2 and the emission area EA of the third pixel P3 are consecutively arrayed along the X-axis.

In the cross-sectional view, a driving element layer 220 is formed on the substrate 110. Thin film transistors are formed on the driving element layer 220. For example, a switching thin film transistor ST and the driving thin film transistor DT are formed at the non-emission area NEA of the second pixel P2. FIG. 5 shows a portion where the driving thin film transistor DT is disposed only, in convenience.

A light emitting element layer 330 is formed on the driving element layer 220. For example, a planarization layer PL is deposited on the passivation layer PAS of the driving element layer 220. A plurality of micro-lens ML can be formed at the planarization layer PL within the emission area EA. For an example, the plurality of micro-lens ML can have a concave shape to the downward direction. For another example, the plurality of micro-lens ML can have a convex shape to the upward direction.

The pixel electrode ANO is formed on the micro-lens ML. A bank BA is formed on the edge of the pixel electrode ANO to define the emission area EA. For example, FIG. 5 shows the emission areas EA of the first pixel P1 and the third pixel P3.

Further, FIG. 5 shows that only the bank BA is disposed on the driving thin film transistor DT in the second pixel P2. The light shielding layer LS is disposed under the driving thin film transistor DT.

With this structure, among the light emitted from the emission area EA of the first pixel P1, the light traveling to the direction of the third pixel P3 is blocked by the light shielding layer LS disposed in the non-emission area NEA formed in the second pixel P2. Therefore, there is no problem of color mixing between two neighboring pixels.

As the second pixel P2 is disposed between the first pixel P1 and the third pixel P3, the distance between the emission layer EL of the first pixel P1 and the emission layer EL of the third pixel P3 is very far. Therefore, the possibility of the lateral leakage current between the first pixel P1 and the third pixel P3 influencing the first pixel P1 and the third pixel P3 is very low. Therefore, even though a light emitting display device with ultra-high pixel density is implemented and the emission area EA becomes closer to each other, image information of the light emitting display device is not distorted due to the lateral leakage current.

In other words, the two closest emission area EA are spaced apart by a non-emission area NEA. Therefore, it has a structure in which length between two neighboring emission areas EA can be ensured to be long enough to be difficult for the lateral leakage current between two neighboring emission areas EA to affect the function of the neighboring pixels. The long length over which the lateral leakage current is transmitted means that the electric resistance between neighboring two emission areas EA increases. Therefore, no lateral leakage current occurs due to the increase in electric resistance between the two emission areas EA. As a result, distortion of the image information in the light emitting display device due to the lateral leakage current does not occur.

Each of the pixels P in the light emitting display device according to the first embodiment of the present discloser has a rectangular shape, and is arrayed in a matrix manner (or, form). However, other shapes and configurations are possible. Further, the emission area EA and the non-emission area NEA can be disposed alternatively and inverted for each pixel P. Accordingly, the emission area EA and the non-emission area NEA are alternately arranged along the horizontal or vertical direction in which the pixels P are arranged. In other word, the emission area EA is arranged in a zig-zag shape (or, manner) in the horizontal or vertical direction. Therefore, the structural feature is that the emission areas EA are arranged diagonally adjacent to each other.

In addition, the light emitting display device according to the first embodiment includes one or more micro-lenses ML. The micro-lens ML can improve the emission efficiency of the light emitted from the emission layer EL. Therefore, higher luminance can be provided.

In a structure including a micro-lens ML, when external light coming from the side of the pixel P is reflected to the common electrode CAT, a concentric rainbow interference pattern can occur due to the shape of the micro-lens ML. This can cause a negative effect on image information.

However, in the light emitting display device according to the first embodiment of the present disclosure, as shown in FIG. 5, the external incident lights from the side of the first pixel P1 can be blacked by the light shielding layer LS. Therefore, there is no distortion of image quality due to the external light reflection.

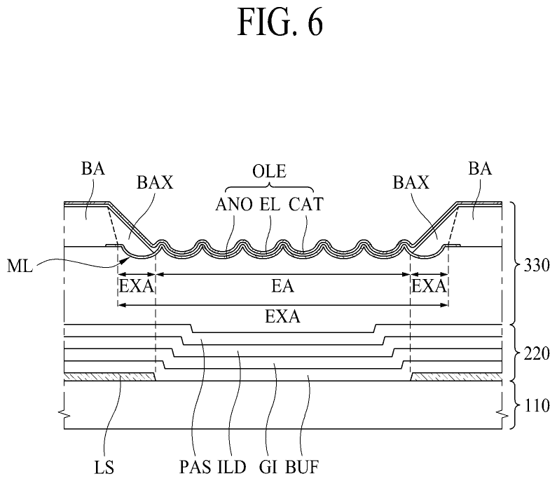

In addition, when applying the pixel array structure according to the first embodiment of the present disclosure to a structure including micro-lens ML, there is an additional advantage of maximizing the aperture ratio. Hereinafter, referring to FIG. 6, structural feature that can secure the maximum aperture ration in the light emitting display device according to the first embodiment will be described. FIG. 6 is a cross-sectional view illustrating a structure for ensuring the maximum aperture ratio in the light emitting display device according to the first embodiment of the present disclosure.

FIG. 6 is a diagram illustrating, as an example, a portion of a pixel P in which a plurality of micro-lenses ML are formed, where the emission area EA is disposed. A driving element layer 220 is formed on the substrate 110. As the driving element layer 200 has the same with the description of FIG. 3, the same explanation will not be duplicated or may be briefly provided.

Referring to FIG. 6, a light emitting element layer 330 is formed on the driving element layer 220. In detail, a planarization layer PL is deposited on the driving element layer 220. A plurality of micro-lenses ML is formed at the planarization layer PL. In particular, the micro-lens ML is preferably formed to have larger area than the emission area EA. For example, the micro-lens ML can be formed as overlapping with some portions (or, areas) of the light shielding layer LS of the neighboring pixels P.

A pixel electrode ANO is formed on the micro-lenses ML. A bank BA is formed on the pixel electrode ANO as covering the circumferences of the pixel electrode ANO and exposing the middle portion of the pixel electrode ANO. Here, the edge of the bank BA can overlap the edge portions of the micro-lens ML. Therefore, side portions of the bank BA can flow down to fill some micro-lens placed on the outermost side. For example, an extended bank portion EXA can be formed at the edge of the bank BA by flowing down the bank BA.

An emission layer EL is deposited on the bank BA, the extended bank EXA and the pixel electrode ANO. A common electrode CAT is deposited on the emission layer EL. As the bank BA is formed to cover the circumferences of the pixel electrode ANO and micro-lens ML, an emission area EA is defined. Under this structure, the extended bank EXA is formed by flowing down an edge portion of the bank BA. Here, due to the extended bank EXA, the emission area EA can be reduced.

However, in the first embodiment of the present disclosure shown in FIG. 6, the pixel electrode ANO and the micro-lens (micro-lenses) ML can have larger area than the designated (or, preset) area of the emission area EA, and the bank BA can be formed to have larger area than the designated area of the emission area EA. To do so, even though the extended bank EXA is formed, the emission area EA can maintain the designated area. Therefore, according to the first embodiment of the present disclosure, as shown in FIG. 6, the emission area EA can secure the maximum aperture ration to correspond to the maximum aperture area determined by the light shielding layer LS.

For the first embodiment of FIG. 5, the bank BA can include hard material that does not being flow down, spilled down or collapsed down. For the case shown in FIG. 5, the area where the bank BA overlaps the pixel electrode ANO is very small, and may not overlap with the micro-lens ML. the micro-lens (micro-lenses) ML can have a shape or structure disposed in the same area as the emission area EA.

However, for the first embodiment of FIG. 6, the bank BA can include a soft material that is easily flow down or collapsed down. For the case shown in FIG. 6, the area where the bank BA overlaps the pixel electrode ANO, and the micro-lens ML is large. For example, the pixel electrode ANO can cover the micro-lens ML with a larger area than the micro-lens ML. Further, the bank BA, especially the extended bank EXA, can be formed to cover a portion of an edge area of the micro-lens ML. Accordingly, in the example of FIG. 6, the micro-lens ML has a shape or structure arranged to extend outside the emission area EA, and overlap the pixel electrode ANO and the bank BA outside the emission area EA.

The bank BA can be made of a black material (or, black resin material). In this case, it is possible to prevent color mixing between two neighboring emission areas EA. The light shielding layer LS is disposed between the emission areas EA, but in the case of a display device with an ultra-high resolution pixel density of 8K or more, a gap between the light shielding layer LS and the emission area EA is formed due to a process margin. In this case, by applying a black resin to the bank BA defining the emission area EA, the color mixing problem between two neighboring pixel can be prevented more reliably.

### Second Embodiment

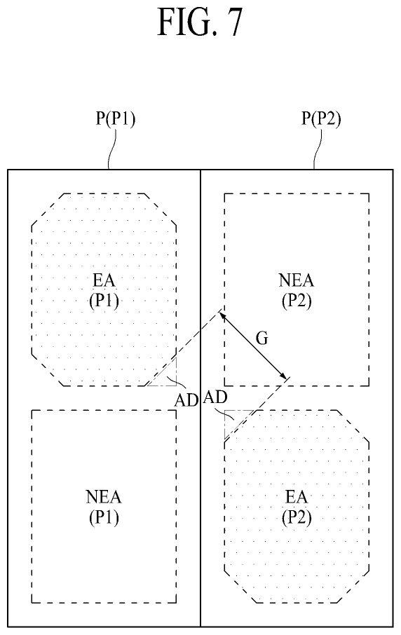

Hereinafter, referring to FIG. 7, a structure of the light emitting display device according to a second embodiment of the present disclosure will be described. FIG. 7 is an enlarged plan view illustrating a structure of a light emitting display according to the second embodiment of the present disclosure.

With reference to FIG. 7, the structure of the second embodiment of the present disclosure is similar to that of the first embodiment. One difference is that the emission area EA of the second embodiment has an octagonal shape, and not a rectangular shape.

One of the features of the light emitting display device according to the present disclosure is that the pixels P are arranged in a matrix manner (or, matrix form). In addition, each pixel P has a long rectangular shape in the vertical direction (e.g., Y-axis direction). Each pixel P is divided into an upper side and a lower side along the vertical direction, with an emission area EA and the non-emission area NEA. In particular, the emission area EA and the non-emission area NEA are arranged alternately between neighboring pixels P.

In detail, neighboring two pixels P, i.e., a first pixel P1 and a second pixel P2, have an emission area EA and a non-emission area NEA, respectively. The emission area EA of the first pixel P1 and the emission area EA of the second pixel P2 are arranged diagonally adjacent to each other. As non-emission area NEA are disposed between the emission area EA in the horizontal direction (e.g., X-axis) and vertical direction (e.g., Y-axis), the spacing between the emission areas EA does not become close enough to affect the performance of each pixel P, even though the size of the emission area EA is decreased, or the pixel density is increased. However, as the size of the emission area EA decreases, or the pixel density increases, the gap between the emission area EA in the diagonal direction can be narrowed.

The light emitting display according to an aspect of the present disclosure has a structure in which the lateral leakage current is prevented between pixels P neighboring in the horizontal or vertical direction in a plan view. However, as the size of the emission area EA decrease, or the pixel density increases, image quality can be affected due to the lateral leakage current between diagonally neighboring emission area EA.

In particular, three light emitting layers including a red-light emitting layer, a blue-light emitting layer and a green-light emitting layer are stacked for implementing the emission layer EA. In order to enhance the color representation, four light emitting layers further including a yellow-color light emitting layer are stacked. In this case, a charge generating layer can be disposed between two light emitting layers. When three light emitting layers are stacked, two charge generating layers are included. When four light emitting layers are stacked, three charge generating layers are included. As the number of the charge generating layers increases, the lateral leakage current can increase.

In the case of having an ultra-high density pixel structure or a multi-layer light emitting layer structure, when the structure according to an embodiment of the present disclosure is applied, a lateral leakage current issue can occur between diagonally neighboring emission areas EA. To solve this issue, it is needed to secure an enough wide gap G between neighboring emission areas EA in the diagonal direction. For this purpose, it is preferable to chamfer the four vertices (or corners) of the rectangular shaped emission area EA to form the emission area EA included in the pixel P into an octagonal shape. It is preferable to set the amount of chamfering of the four vertices to maximize the area of the emission area EA, while ensuring a sufficient distance between diagonally neighboring emission areas EA to prevent the lateral leakage current.

FIG. 7 shows that each emission area EA of two neighboring pixels P1 and P2 has a structure in which the vertices (or, corners) facing each other in the diagonal direction are chamfered. A triangular area AD removed by chamfering can correspond to an area where color distortion or color loss can occur due to the lateral leakage current when chamfering is not performed.

As another example of a different shape of the emission area EA to prevent lateral leakage current in the diagonal direction, each emission area EA can have a hexagonal shape. In this case, a wider distance between diagonally adjacent emission areas EA can be ensured. This example can ensure that an excellent effect can be obtained in preventing lateral leakage current between neighboring emission areas EA in the case of the bottom emission type where the pixel density has increased to 8K or more.

As still another example, each emission area EA can have either a circular shape or an oval (or elliptical) shape. The emission area EA having a circular shape or an elliptical shape can ensure that the distance between the emission areas EA adjacent to each other in the diagonal direction is wider than the distance between the emission area EA adjacent to the left and right directions or up and down directions.

### Third Embodiment

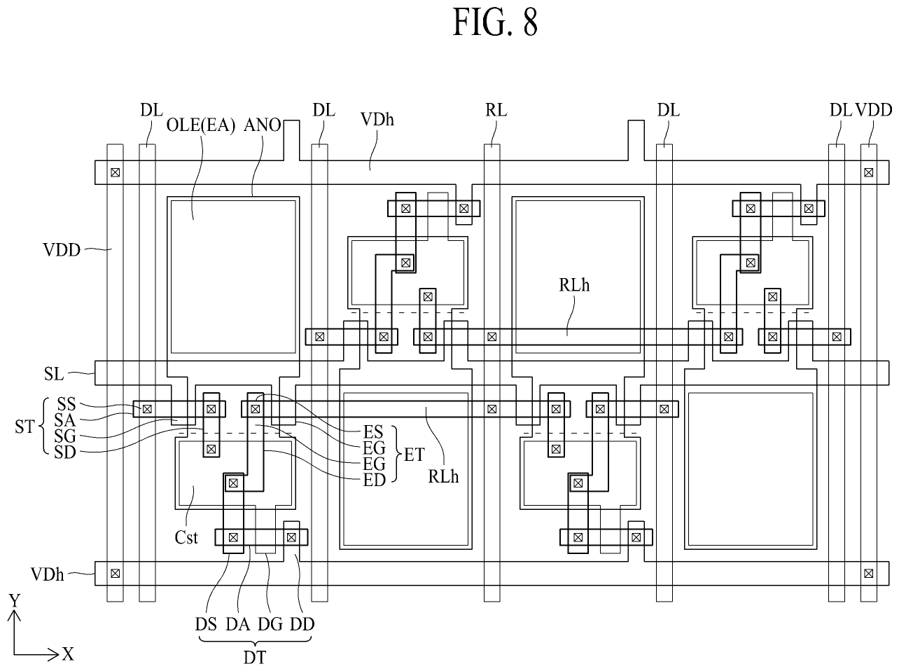

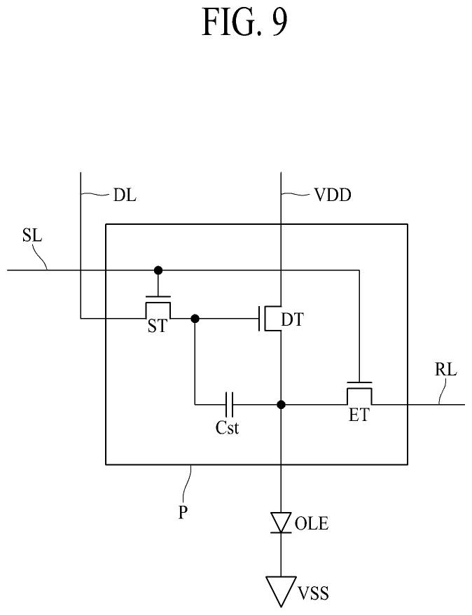

Hereinafter, referring to FIGS. 8 and 9, a structure of the light emitting display device according to a third embodiment of the present disclosure will be described. FIG. 8 is an enlarged plan view illustrating a structure of 4-pixel array in a light emitting display device according to the third embodiment of the present disclosure. FIG. 9 is an equivalent circuit diagram for one pixel in the light emitting display device according to the third embodiment of the present disclosure.

Referring to FIGS. 8 and 9, the light emitting display device according to the third embodiment of the present disclosure has the same (or similar) arrangement structure with that of the first embodiment. One difference is directed to the elements included in one pixel P. For example, in the first embodiment, as shown in FIG. 2, one pixel P has a 2T1C structure in which two thin film transistors ST and DT and one storage capacitor Cst are included. On the other hand, in the third embodiment, as shown in FIG. 8, one pixel P has a 3T1C structure in which three thin film transistors ST, DT and ET and one storage capacitor Cst are included. Detailed descriptions of the same elements as those in the first embodiment will be omitted unless provided below.

The light emitting display device according to the third embodiment of the present disclosure includes a plurality of pixels P arrayed in a matrix manner. On the substrate 110, a scan line SL, a data line DL, a sensing line RL and a driving current line VDD are disposed. For example, the scan line SL is running to an X-axis direction on the substrate 110. The data line DL, the sensing line RL and the driving current line VDD are running to a Y-direction on the substrate 110.

For example, FIG. 8 shows a structure in which 4 pixels P are arrayed along the X-direction. Four data lines DL are disposed, one sensing line RL is disposed for each two data lines DL. The data lines DL and the sensing lines RL can be arranged at equal intervals along the X-axis. The driving current line VDD can be respectively disposed on the left side and the right side of the four data lines DL.

The sensing line RL is connected to a horizontal sensing line RLh. The horizontal sensing line RLh is a line for supplying a sensing signal to a pixel P located across from one pixel P. The driving current line VDD is connected to a horizontal driving current line VDh. The horizontal driving current line VDh is a line for supplying a driving power to a pixel P located across from one pixel P. The horizontal driving current line VDh can connect the driving current lines VDD arranged in each of the four pixels to each other.

One pixel P can be defined by two data lines DL and two horizontal driving current line VDh. Otherwise, one pixel can be defined by one data line DL, one sensing line RL and two horizontal driving current line VDh. The scan line SL can be disposed as crossing the middle portion of the pixel P. One pixel P can be divided into two portions including an upper portion and a lower portion based on the scan line SL. One pixel P can have an emission area EA disposed in the upper portion, and a non-emission area NEA disposed in the lower portion. Additionally, a neighboring pixel P can have a non-emission area NEA disposed in the upper portion, and an emission area EA disposed in the lower portion.

In one pixel P, especially within the non-emission area NEA, a scan thin film transistor ST, a sensing thin film transistor ET, a driving thin film transistor DT and a storage capacitor Cst are disposed. In one pixel P, especially within the emission area EA, a light emitting diode OLE is disposed. A pixel electrode ANO of the light emitting diode OLE can be formed over the emission area EA and the non-emission area NEA. The pixel electrode ANO is connected to the driving thin film transistor DT at the non-emission area NEA, and extended to the emission area EA to form a first electrode of the light emitting diode OLE.

The scan thin film transistor ST is disposed (or connected) between the scan line SL and the data line DL. The sensing thin film transistor (or connected) ET is disposed between the scan line SL and the sensing line RL. The driving thin film transistor DT is disposed (or connected) among the driving current line VDD, the scan thin film transistor ST and the sensing thin film transistor ET.

The switching thin film transistor ST operates in response to the scan signal supplied through the scan line SL so that the data signal supplied through the data line DL is stored as a data voltage in the storage capacitor Cst. The driving thin film transistor DT operates so that a driving current flows between the driving current line VDD and the low-power line VSS according to the data voltage stored in the storage capacitor Cst. The light emitting diode OLE emits light according to the amount of a driving current controlled by a driving thin film transistor DT. The sensing thin film transistor ET is a circuit placed in the pixel to compensate for the threshold voltage of the driving thin film transistor DT. The sensing thin film transistor ET is connected to the sensing node where the drain electrode DD of the driving thin film transistor DT and the pixel electrode ANO of the light emitting diode OLE are connected. The sensing thin film transistor ET operates to supply an initialization voltage transmitted through the sensing line RL to the sensing node, or to detect the voltage or current of the sensing node.

In the switching thin film transistor ST, the source electrode SS is connected to the data line DL and the drain electrode SD is connected to the gate electrode DG of the driving thin film transistor DT. In the driving thin film transistor DT, the drain electrode DD is connected to the driving current line VDD, and the source electrode DS is connected to the pixel electrode ANO. In the storage capacitor Cst, a first electrode is connected to the gate electrode DG of the driving thin film transistor DT, and a second electrode is connected to the pixel electrode ANO of the light emitting diode OLE.

In the light emitting diode OLE, the pixel electrode ANO is connected to the source electrode DS of the driving thin film transistor DT, and the common electrode CAT is connected to the low-power line VSS. In the sensing thin film transistor ET, the source electrode ES is connected to the sensing line RL, and the drain electrode ED is connected to the sensing node which is the pixel electrode ANO of the light emitting diode OLE. The semiconductor layer EA of the sensing thin film transistor ET is overlapped with the gate electrode EG branched from the scan line SL. The area of the semiconductor layer EA overlapped with the gate electrode EG is defined as the channel region.

In the light emitting display device according to the third embodiment of the present disclosure, a non-emission area NEA is disposed between two emission areas EA located in each of the two neighboring pixels P. Therefore, the lateral leakage current can be prevented. In addition, the light leakage between two neighboring pixels P can be prevented.

Furthermore, even though additional elements such as the sensing thin film transistor ET are added, the maximum area of the emission area EA can be secured. Even though the size of the pixel electrode ANO is increased in the area where the emission area EA is placed, the pixel electrode ANO does not contact the pixel electrode ANO of neighboring pixels P, so the size of the pixel electrode ANO can be maintained in the maximum size. Accordingly, brighter luminance can be provided with the lower power consumption.

The dotted line shown in FIG. 8 is a cutting line for disconnecting the pixel electrode ANO and the thin film transistors ST, ET and DT in the repair process to darken a defective pixel. One cutting line is set at a position that can simultaneously cut the connectivity of the scanning thin film transistor ST, the sensing thin film transistor ET and the driving thin film transistor DT from the pixel electrode ANO. Therefore, the margin area for arranging the cutting line can be minimized. As a result, the aperture ratio of the emission area EA can be further secured, or more space for arrangement of elements can be secured in the non-emission area NEA.

In the various embodiments of the present disclosure described above, the case where the pixel P has a long rectangular shape in the vertical direction (e.g., Y-axis direction) has been described. An emission area EA and a non-emission area NEA are disposed in the upper portion and the lower portion, otherwise in the lower portion and the upper portion along the vertical direction.

The present disclosure is not limited thereto. For instance, the pixel can have a long rectangular shape in a horizontal direction (e.g., X-axis direction). In this case, the emission area and the non-emission area can be arranged in the left portion and the right portion, otherwise in the right portion and left portion along the horizontal direction.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment can be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description.

In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

What is claimed is:

1. A light emitting display comprising:
a plurality of pixels disposed on a substrate; and
a first area and a second area both disposed in each of the plurality of pixels,
wherein the plurality of pixels include a first pixel and a second pixel, and
wherein the first area of the first pixel is disposed adjacent to the second area of the second pixel.

2. The light emitting display according to claim 1, wherein the first area includes an emission area, and
wherein the second area includes a non-emission area.

3. The light emitting display according to claim 2, further comprising:
a light shielding layer disposed in the non-emission area.

4. The light emitting display according to claim 2, wherein the emission areas are arrayed in a zig-zag manner along a horizontal direction and a vertical direction.

5. The light emitting display according to claim 2, wherein the emission areas are disposed in a diagonal direction.

6. The light emitting display according to claim 1, wherein the emission area includes:
a pixel electrode;
an emission layer disposed on the pixel electrode; and
a common electrode disposed on the emission layer.

7. The light emitting display according to claim 6, further comprising:
a micro-lens disposed under the pixel electrode.

8. The light emitting display according to claim 7, further comprising:
a bank covering a circumferential area of the pixel electrode, and exposing middle portions of the pixel electrode,
wherein the micro-lens overlaps a portion of the pixel electrode and a portion of the bank outside the emission area.

9. The light emitting display according to claim 8, wherein the bank includes a black material.

10. The light emitting display according to claim 1, wherein the first area of the first pixel and the second area of the second pixel are disposed adjacent to each other in a horizontal direction on a surface of the substrate.

11. The light emitting display according to claim 1, wherein the first area of the first pixel and the second area of the second pixel are disposed adjacent to each other in a vertical direction on a surface of the substrate.

12. A light emitting display comprising:
a substrate;
a plurality of pixels defined on the substrate,
wherein each of the plurality of pixels includes an emission area at one side and a non-emission area at the other side of a corresponding pixel,
wherein the emission areas and the non-emission areas are alternatively arranged in a first direction and a second direction perpendicular to the first direction on the substrate.

13. The light emitting display according to claim 12, wherein the emission area of one pixel is adjacent to the non-emission areas of neighboring pixels of the one pixel, and
wherein the non-emission area of the one pixel is adjacent to the emission areas of neighboring pixels of the one pixel.

14. The light emitting display according to claim 12, further comprising:
a light shielding layer disposed in the non-emission area.

15. The light emitting display according to claim 12, wherein the emission area includes:
a pixel electrode;
an emission layer on the pixel electrode; and
a common electrode on the emission layer.

16. The light emitting display according to claim 15, further comprising:
a micro-lens under the pixel electrode.

17. The light emitting display according to claim 16, further comprising:
a bank covering circumferential area of the pixel electrode, and exposing middle portions of the pixel electrode,
wherein the micro-lens overlaps a portion of the pixel electrode and a portion of bank outside the emission area.

18. The light emitting display according to claim 17, wherein the bank includes a black material.
